(19) United States
(12) Patent Application Publication
(10) Pub. No.: US 2006/0057824 A1
(43) Pub. Date: Mar. 16, 2006

(54) Apparatus for producing nitride semiconductor, method for producing nitride semiconductor, and semiconductor laser device obtained by the method

(76) Inventors: Masahiro Araki, Ube-shi (JP); Eiji Yamada, Hiroshima (JP); Takayuki Yuasa, Ikoma-gun (JP); Yuhzoh Tsuda, Sakurai-shi (JP); Nakao Akutsu, Tokyo (JP)

Correspondence Address: HARNESS, DICKEY & PIERCE, P.L.C., P.O. BOX 8910, RESTON, VA, 20195, US

(21) Appl. No.: 11/221,951

(22) Filed: Sep. 9, 2005

(30) Foreign Application Priority Data
Sep. 10, 2004 (JP) 2004-264162

(51) Int. Cl. C23C 16/00; H01L 21/20

(52) U.S. Cl. 438/478; 118/715

(57) ABSTRACT

The present invention relates to an apparatus for producing a nitride semiconductor by crystal-growing the nitride semiconductor on a substrate by diffusing a gas containing a source gas of group III element and a source gas of group V element. The gas is diffused in parallel with the substrate and from upstream to downstream. The apparatus has the substrate housed in the apparatus and a flow channel for allowing the gas to flow in the flow channel. The apparatus also has a plurality of protrusions provided on an inner wall of the flow channel. A partition for causing the source gas of group III element and the source gas of group V element to be introduced separately into the flow channel is provided on the upstream portion of the flow channel and in a horizontal direction. The protrusions are formed on the upper and lower surfaces of the partition. With this structure, the source gas of group III element and the source gas of group V element are more uniformly mixed before the source gases are supplied.

This non-provisional application claims priority under 35 U.S.C. §119(a) on Japanese Patent Application No. 2004-264162 filed in Japan on Sep. 10, 2004, the entire contents of which are hereby incorporated by reference.

### BACKGROUND OF THE INVENTION

1) Field of the Invention

The present invention generally relates to an apparatus for producing a nitride semiconductor by crystal-growing the nitride semiconductor on a substrate by diffusing, from upstream to downstream, a gas that contains a source gas of group III element and a source gas of group V element. More specifically, the invention relates to an improved apparatus for producing a nitride semiconductor which makes the characteristics of the nitride semiconductor device uniform over the plane. The present invention also relates to an improved method for producing a nitride semiconductor laser device which makes the characteristics of the nitride semiconductor device uniform over the plane. The present invention also relates to a nitride semiconductor laser device obtained by the method.

2) Description of the Related Art

Nitride-based III-V compound semiconductor crystals represented by GaN, AlN, InN, and mixed crystals thereof are being paid attention to as semiconductor laser devices that oscillate in the ultraviolet-visible region. Nitride semiconductors used for semiconductor laser devices are produced by using a metal organic chemical vapor deposition (MOCVD) apparatus, molecular beam epitaxy (MBE) apparatus, hydride vapor phase epitaxy (HVPE) apparatus, or the like. Most promising among these is the MOCVD apparatus, which provides the nitride semiconductor laser with excellent characteristics. Nitride semiconductor lasers produced by using the MOCVD apparatus are known to have, as life characteristics, an estimated duration of 15000 hours at 30 mW and 60° C. (see, for example, Shin-ichi Nagahama et al., “High-Power and Long-Lifetime InGaN Multi-Quantum-Well Laser Diodes Grown on Low-Dislocation-Density GaN Substrates”, Jpn. J. Appl. Phys., July 2000, Vol.7A, Part2, pp. L647-L650).

FIG. 8 shows a conventional MOCVD apparatus that grows nitride semiconductors. MOCVD apparatus 301 has flow channel 302, and in flow channel 302, substrate tray 311 that holds substrate 310, susceptor 312 that acts as a heat source, RF coil 313 that heats susceptor 312, and susceptor protecting gas line 309 that prevents attachment of nitride semiconductor to susceptor 312. The portion of flow channel 302 formed on the upstream side of substrate 310 is divided into three layers by partitions, the layers including, from the bottom, source NH₃ gas line 306, source MO gas line 307, and protection gas line 308.

Generally, for uniformity of the concentration ratio of the mixed gas, the structure of the flow channel in the MOCVD apparatus is designed for laminar gas flow. Laminar gas flow stabilizes the flow of gas and realizes semiconductor layers with excellent reproducibility.

However, producing nitride semiconductor lasers of GaN, AlGaN, AlInGaN, etc., with the use of conventional MOCVD apparatuses are problematic in the following respects. First, the viscosity of MO gas, which is a source gas of group III element (Ga, Al, In), differs significantly from the viscosity of NH₃ gas, which is a source gas of group V element (N). This prevents the uniformity of the concentration ratio distribution of the source gas of group III element and the concentration ratio distribution of the source gas of group V element over the plane of the substrate over which nitride semiconductors are crystal-grown to give a laminated structure of thin films. As a result, the characteristics of resulting nitride semiconductor lasers are not uniform, presenting the problem of unsatisfactory yields.

Especially when increasing the size of the apparatus in accordance with an increase in the size of the substrate over which nitride semiconductors are crystal-grown to give a laminated structure of thin films, the mixture of the source gases becomes less uniform over the plane of the substrate, presenting the problem of further deteriorating the uniformity of the characteristics of nitride semiconductor lasers. Further, this causes a wide variation in optical characteristics including laser emission wavelengths of the lasers, also causing the problem of unsatisfactory yields.

To mix the source gases uniformly over the substrate plane, a board that makes gas flow laminar flow can be provided. In this case, however, the concentration ratio distribution of the source gases largely varies with the shape and location of the board that makes gas flow laminar flow. Thus, to obtain the desired nitride semiconductor, it is required to optimize the amount of the source gases supplied every time the shape and location of the current plate are changed. This presents the problem of very poor efficiency.

### SUMMARY OF THE INVENTION

In view of the foregoing and other problems, it is an object of the present invention to provide an improved apparatus for producing a nitride semiconductor which makes the characteristics of the nitride semiconductor device uniform throughout the substrate plane.

It is another object of the present invention to provide a MOCVD apparatus which can make a film that laser characteristics are uniform even when the size of the substrate over which nitride semiconductors are crystal-grown to give a laminated structure of thin films is increased.

It is another object of the present invention to provide an improved method for producing a nitride semiconductor which makes the characteristics of the nitride semiconductor device uniform throughout the substrate plane.

It is another object of the present invention to provide a nitride semiconductor laser device in which laser characteristics are uniform throughout the substrate plane.

In order to accomplish the above and other objects, the apparatus according to the present invention is an apparatus for producing a nitride semiconductor by crystal-growing the nitride semiconductor on a substrate by diffusing a gas containing a source gas of group III element and a source gas of group V element, the diffusing of the gas being in parallel with the substrate and from upstream to downstream. The apparatus comprises: a flow channel housing the substrate and for allowing the gas to flow in the flow channel; and a plurality of protrusions on an inner wall of the flow channel.

With this structure, the protrusions on an inner wall of the flow channel cause the gases to be stirred. As a result, the concentration ratio distribution of the source gas of group III element and the concentration ratio distribution of the source gas of group V element become uniform throughout the substrate plane over which nitride semiconductors are crystal-grown to give a laminated structure of thin films.

The protrusions are preferably formed on the upstream side of the substrate in the flow channel. With this structure, the concentration ratio distribution of the source gas of group III element and the concentration ratio distribution of the source gas of group V element become more uniform before the source gases are supplied to the substrate.

In a preferred embodiment of the present invention, a partition is provided for causing the source gas of group III element and the source gas of group V element to be introduced separately into the flow channel, the partition being formed on an upstream portion of the flow channel and extending in a horizontal direction. The protrusions are formed on at least one, or preferably both, of the upper and lower surfaces of the partition. With this structure, the protrusions formed on the partition cause the source gas of group III element and the source gas of group V element to be stirred. As a result, the source gas of group III element and the source gas of group V element are uniformly distributed.

The protrusions are hemisphere-shaped, campanulate-shaped, or columnar-shaped. If the protrusions are hemisphere-shaped, the laminar flow of the source gases is not disturbed, thus maintaining the stability of gas flow.

In the case where the protrusions are campanulate-shaped or column-shaped, a bottom surface of each of the protrusions are preferably equilateral-polygon-shaped or circle-shaped.

Preferably, the centers of the bottom surfaces of the protrusions are equally spaced from each other. Location of the centers of the bottom surfaces of the protrusions with equal distances therebetween efficiently makes the concentration ratio distribution of the source gases uniform.

Preferably, the plurality of protrusions are arranged to become an equilateral triangle if the center of each bottom in three adjoined protrusions is connected.

The plurality of protrusions may be arranged to become an equilateral quadrangle if the center of each bottom in four adjoined protrusions is connected.

According to another aspect of the present invention, there is provided a method for producing a nitride semiconductor by crystal-growing the nitride semiconductor on a substrate by supplying thereonto a mixture gas containing a source gas of group III element and a source gas of group V element, the method comprising: stirring the source gas of group III element and the source gas of group V element; and supplying the stirred source gases onto the substrate.

According to this invention, the source gas of group III element and the source gas of group V element, while having different viscosities from each other, are stirred before supplied onto the substrate, thus making the concentration ratio distribution of the sources gases uniform throughout the substrate plane. As a result, each nitride semiconductor is prepared uniformly throughout the substrate plane.

In this preferred embodiment of the present invention, the source gas of group III element and the source gas of group V element are stirred separately; and the separately stirred source gases are supplied onto the substrate.

According to this invention, the source gas of group III element and the source gas of group V element, while having different viscosities from each other, are stirred separately from each other and supplied onto the substrate. When supplied onto the substrate, each of the source gases is uniformly mixed.

Preferably, the source gas of group III element and the source gas of group V element are diffused in parallel with the substrate and from upstream to downstream.

Preferably, the nitride semiconductor is crystal-grown by the metal organic chemical vapor deposition method.

In the above method, the size of the substrate is from 2 to 3 inches.

The device according to another aspect of the present invention relates to a nitride semiconductor laser device produced by the method described above.

The term substrate as used herein is intended to mean a nitride semiconductor substrate preferably composed of AlₓGa_{y}In_{z}N (0≦x≦1, 0≦y≦1, 0≦z≦1, x+y+z=1). In this nitride semiconductor substrate, approximately 20% or less of the nitrogen element, which is a constituent of the substrate, may be substituted with any one element selected from the group consisting of As, P, and Sb.

The above nitride semiconductor substrate may contain n-type or p-type dopant impurities. Examples of impurities include Cl, O, S, Se, C, Te, Si, Ge, Zn, Cd, Mg, and Be. Preferable impurities for a nitride semiconductor substrate with n-type conductivity include Si, Ge, S, Se, and Te. Preferable impurities for a nitride semiconductor substrate with p-type conductivity include Cd, Mg, and Be. The total amount of the impurities contained is preferably from 5×10¹⁶/cm³ to 5×10²⁰/cm³.

The term nitride semiconductor layer crystal-grown over the nitride semiconductor substrate as used herein is intended to mean a layer composed of AₓGa_{y}In_{z}N (0≦x≦1, 0≦y≦1, 0≦z≦1, x+y+z=1). In this nitride semiconductor layer, approximately 20% or less of the nitrogen element, which is a constituent of the substrate, may be substituted with any one element selected from the group consisting of As, P, and Sb.

The above nitride semiconductor layer may contain n-type or p-type dopant impurities. Examples of impurities include Cl, O, S, Se, C, Te, Si, Ge, Zn, Cd, Mg, and Be. Preferable impurities for a nitride semiconductor layer with n-type conductivity include Si, Ge, S, Se, and Te. Preferable impurities for a nitride semiconductor layer with p-type conductivity include Cd, Mg, and Be. The total amount of the impurities contained is preferably from 5×10¹⁶/cm³ to 5×10²⁰/cm³.

The term active layer as used herein is a general term for a well layer and a layer composed of a well layer and a barrier layer. For example, an active layer of single quantum well structure is either composed of a well layer alone or composed of a barrier layer/well layer/barrier layer. An active layer of multi-quantum well structure is composed of a plurality of well layers and barrier layers.

In crystallography, when an index associated with crystal plane or crystal orientation is negative, it is common practice to place a bar above the absolute value. In this specification, however, instead of this notation, the negativity of index is indicated by a minus sign immediately before the absolute value.

The apparatus for producing a nitride semiconductor according to the present invention makes the concentration ratio distribution of the source gases uniform throughout the substrate plane by providing a plurality of protrusions on an inner wall of the flow channel.

The laser emission wavelength of the nitride semiconductor laser produced by using the apparatus for producing a nitride semiconductor according to the present invention has its variation restricted to 1 nm or less throughout the substrate plane. Further, the variation of mixed crystal ratio of the AlGaN layer and the variation of thickness of the AlGaN layer throughout the substrate plane are restricted to several %. This results in nitride semiconductor laser devices with less varied optical characteristics and improved yields.

### BRIEF DESCRIPTION OF THE DRAWINGS

FIG. 1 is an enlarged cross-section of main portions of an apparatus for producing a nitride semiconductor according to the present invention.

FIG. 2(a) is an enlarged cross-section of the portions circled by the dotted line shown in FIG. 1.

FIG. 2(b) is an enlarged plan view of the portions circled by the dotted line shown in FIG. 1.

FIG. 3 is a schematic cross-section of a semiconductor laser device according to an embodiment of the present invention.

FIG. 4 is a graph showing the number of times (%) of laser emission wavelength in a semiconductor laser device according to comparative example 1.

FIG. 5 is a graph showing the number of times (%) of laser emission wavelength in a semiconductor laser device according to an embodiment of the present invention.

FIG. 6 is a graph showing the in-plane distribution (%) of thickness of a first n-type AlGaN cladding layer of a nitride semiconductor laser according to an embodiment of the present invention and the in-plane distribution (%) of thickness of a first n-type AlGaN cladding layer of a nitride semiconductor laser according to comparative example 1.

FIG. 7 is a graph showing the in-plane distribution (%) of Al composition of a first n-type AlGaN cladding layer of a nitride semiconductor laser according to an embodiment of the present invention and the in-plane distribution (%) of Al composition of a first n-type AlGaN cladding layer of a nitride semiconductor laser according to comparative example 1.

FIG. 8 is a cross-section of main portions of a conventional MOCVD apparatus.

### DESCRIPTION OF THE PREFERRED EMBODIMENTS

Preferred embodiments of the present invention will be described with reference to the drawings. It will be appreciated that the present invention is not limited by these embodiments.

Apparatus for Producing Nitride Semiconductor

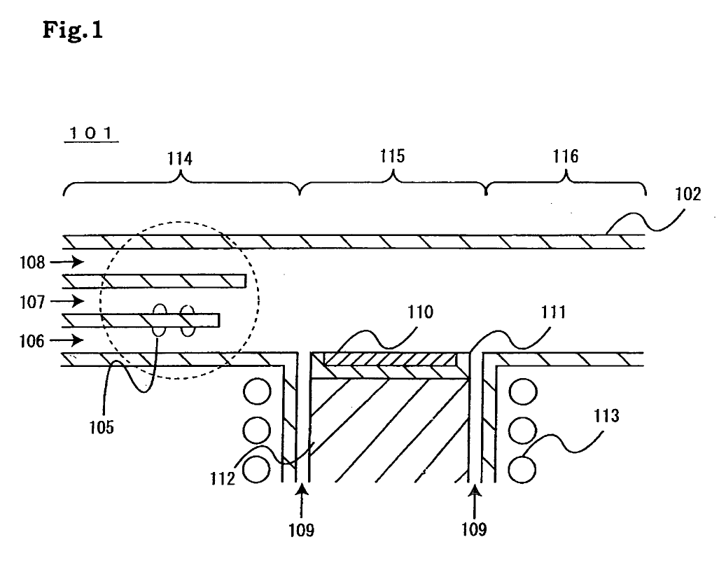

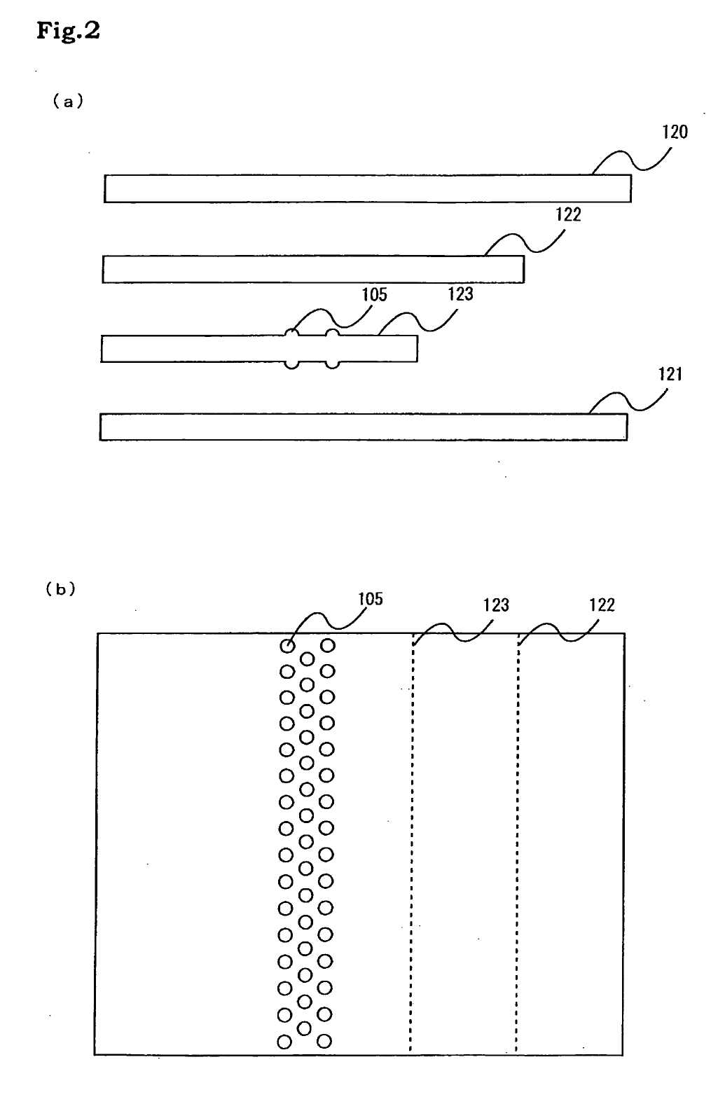

FIG. 1 is an enlarged cross-section of main portions of a producing apparatus of a nitride semiconductor according to the present invention. FIG. 2(a) is an enlarged cross-section of the portions circled by the dotted line shown in FIG. 1. FIG. 2(b) is an upper enlarged view of the portions circled by the dotted line shown in FIG. 1. The apparatus for producing a nitride semiconductor of the present invention is an MOCVD apparatus. A feature of the present invention is provision of a plurality of protrusions on an inner wall of the flow channel of the MOCVD apparatus. In this respect the MOCVD apparatus of the invention differs from conventional MOCVD apparatuses.

MOCVD apparatus 101 of the present invention has flow channel 102, and in flow channel 102, tray 111 that holds substrate 110, susceptor 112 that acts as a heat source, RF coil 113 that heats susceptor 112, and susceptor protecting gas line 109 that prevents attachment of nitride semiconductor to susceptor 112. Flow channel 102 is divided into upstream flow channel 114, over-the-substrate flow channel 115, and downstream flow channel 116. Upstream flow channel 114, which is formed on the upstream side of substrate 110, has two partitions formed in the horizontal direction. The two partitions divide upstream flow channel 114 into three layers including, from the bottom, source NH₃ gas line 106, source MO gas line 107, and protection gas line 108. A plurality of protrusions 105 are provided on the upper and lower surfaces of the partition between source NH₃ gas line 106 and source MO gas line 107.

Similarly to a conventional MOCVD apparatus, this MOCVD apparatus is a horizontal-type vapor deposition apparatus and grows nitride semiconductor layers over the surface of substrate 110, which is mounted on the upper surface of susceptor 112, by diffusing source gases in parallel with the surface of substrate 110. The source gases in the present invention are supplied from a source gas supply portion, not shown, and flow through upstream flow channel 114 onto the surface of substrate 110. Surplus source gas flows through downstream flow channel 116 and is released from an exhaust passage (not shown). The shape of upstream and downstream flow channels 114 and 116 are designed for laminar gas flow.

Flow channel 102 is generally made of quartz glass for thermal stability purposes. Carbon, silicon carbide (SiC), boron nitride (BN), and tantalum carbide (TaC) can be used instead of the quartz glass.

As shown in FIG. 1, substrate 110, over which nitride semiconductors are crystal-grown to give a laminated structure of thin films, is mounted over susceptor 112, which acts as a heat source, via tray 111, in which the substrate is set. In the vicinity of susceptor 112 are provided RF coil 113 that heats susceptor 112 and susceptor protecting gas line 109 that prevents attachment of nitride semiconductor to susceptor 112.

Susceptor 112 revolves at the rate of from 5 to 30 revolutions per minute. Tray 111 and substrate 110, which are above susceptor 112, revolve at the same rate.

Partitions

In the embodiment of FIG. 1, upstream flow channel 114 is partitioned by two partitions in order for three-laminar flow. As shown in FIG. 2, two partitions 122 and 123 are provided between upper surface 120 of upstream flow channel 114 and lower surface 121 of upstream flow channel 114. For example, the three-laminar flow is composed of, from the bottom, source NH₃ gas line 106, source MO gas line 107, and protection gas line 108. Source NH₃ gas line 106 is for the flow of a source NH₃ gas and H₂ gas that acts as carrier gas or H₂ gas and silane gas (SiH₄). Source MO gas line 107 is for the flow of a source MO gas and H₂ gas or N₂ gas that acts as carrier gas. Protection gas line 108 is for the flow of H₂ gas or a mixture gas of N₂ gas and NH₃ gas. In the three gas lines, the locations of source NH3 gas line 106 and source MO gas line 107 are interchangeable. That is, the three-laminar flow may be composed of, from the bottom, the source MO gas line, source NH₃ gas line, and protection gas line.

While in the embodiment of FIG. 2 two partitions 122 and 123 are formed so that flow channel 102 is divided into three equal heights, the locations of partitions 122 and 123 are not particularly limited. For example, they may be formed so that the height of the protection gas line is larger than the heights of the source NH₃ gas line and source MO gas line.

While in the embodiment of FIG. 1 three-laminar flow is employed, this is not to be restrictive and two-laminar flow may be employed.

Protrusions

A feature of the present invention is provision of a plurality of protrusions on an inner wall of the flow channel including the partitions. In the embodiment of FIG. 1, a plurality of protrusions 105 are provided on the upper and lower surfaces of the partition between source NH₃ gas line 106 and source MO gas line 107.

Shape of the Protrusions

The shape of the protrusions provided on an inner wall of the flow channel of the present invention is not particularly limited; for example, they may be hemisphere-shaped, campanulate-shaped (e.g., shapes of pyramids such as trigonal pyramids and quadrangular pyramids, or of cones), column-shaped (e.g., shapes of prisms such as triangular prisms and quadratic prisms, or of cylinders). The bottom surface of the pyramid or prism may not necessarily be equilateral-polygon-shaped. The bottom surface of the prism or cylinder may be ellipse-shaped. The campanulate shape may be such that the perpendicular line running from the top to the bottom surface of the shape shifts from the center of the bottom surface. The column shape may be such that the perpendicular line running from the center of gravity of the top surface of the column down to the bottom surface shifts from the center of gravity of the bottom surface. In the case of campanulate-shaped or column-shaped protrusions, the bottom surfaces are preferably equilateral-polygon-shaped or circle shaped for ease of production and effective mixture of the source gases. The most preferable among the above shapes for the protrusions is the shape of hemisphere.

Size of the Protrusions

The size of the protrusions provided on an inner wall of the flow channel of the present invention is relatively decided from the size of the inner diameter in the width direction of flow channel 102. This is considered to be due to the fact that in lateral-type MOCVD apparatuses source gas is easy to distribute in the width direction. Nevertheless, the actual size value may be in the range provided below regardless of the size of the flow channel. This is because of the following reason. In the apparatus for producing a nitride semiconductor of the present invention, while the laminar flow of the source gases is maintained as a whole, source gas at the interface of the layers is stirred by the protrusions. This makes the concentration ratio distribution of the source gases uniform throughout the substrate plane. Thus, even with a large-sized substrate, provision of protrusions according to the present invention makes it easy to make the concentration ratio distribution of the source gases uniform.

The size of the protrusions is as follows: the height is from 1 mm to 10 mm, preferably from 2 mm to 8 mm; and the width is from 1 mm to 10 mm, preferably from 2 mm to 8 mm. In the case of campanulate-shaped protrusions, the above width corresponds to the largest diameter of the bottom surface of the campanulate-shape. If the height and width of the protrusions are larger or smaller than the above specified values, the effect of uniformly distributing the source gas of group III element and the source gas of group V element reduces. In the case of hemisphere-shaped protrusions, the hemisphere has the relationship “length of the base≧height.”

Arrangement of the Protrusions

The protrusions may be arranged periodically or non-periodically. Periodic arrangement in a particular pattern is preferred in that the uniformity of the concentration ratio of the source gases is improved more effectively throughout the substrate plane. The expression periodic arrangement in a particular pattern is intended to mean that neighboring protrusions are equally spaced from each other. Equal spacing of neighboring protrusions in turn means that the centers of gravity of the neighboring protrusions are equally spaced from each other. As shown in the embodiment of FIG. 2(b), drawing a line connecting the centers of three neighboring protrusions results in an equilateral triangle. The protrusions may not necessarily be arranged in an equilateral-triangle pattern but may be arranged in an equilateral-quadrangle pattern. The distance at which the protrusions are spaced from each other may be the distance between the centers of gravity of the bottom surfaces of neighboring protrusions, an example being from 1 mm to 10 mm.

Forming of the Protrusions

Forming of the protrusions in upstream flow channel 114, which is formed on the upstream side of the substrate, is preferred for making the source gases uniform. Where in the inner walls of flow channel 102 to form the protrusions may be determined conveniently depending on the shape and size of flow channel 102. Specifically, the shortest distance between the center of substrate 110 and the region where the protrusions are formed may be from ½ to 3 times the width of the flow channel, preferably from 1 to 2.5 times. For example, when the flow channel is 100 mm wide, then the shortest distance is from 50 mm to 300 mm, preferably from 100 mm to 250 mm.

In the inner walls of flow channel 102, the protrusions may be formed on the inner wall of upper surface 120 of the flow channel, the inner wall of lower surface 121 of the flow channel, the upper and lower surfaces of partition 122 between the protection gas line and group III source gas line, or the upper and lower surfaces of partition 123 between the group III source gas line and group V source gas line. When provided on the partition, the protrusions may be formed either on the upper or lower surface of the partition. It is preferred that the protrusions are formed on partition 123, which is between the group III source gas line and group V source gas line. When protrusions 105 are provided on the upper and lower surfaces of partition 123, which is between the group III source gas line and group V source gas line, the group III source gas and group V source gas are stirred separately by the protrusions. As a result, the stirred source gases are mixed with each other, which, it is considered, makes the densities of the source gases more uniform.

The MOCVD apparatus according to the present invention is similar to conventional MOCVD apparatuses except that a plurality of protrusions are provided on an inner wall of the flow channel. Also, the “epitaxial growth of nitride semiconductor layers” and “element-making process” which will be described in the embodiments of the present invention below are similar to conventional known processes. For this reason, the embodiments below contain general descriptions of epitaxial growth of nitride semiconductor layers and of the element-making process.

As has been described hereinbefore, the nitride semiconductor laser devices that utilize nitride semiconductors produced by the apparatus for producing a nitride semiconductor according to the present invention have uniform composition and thickness of the nitride semiconductor layer throughout the substrate, thus realizing reduced variations in optical characteristics and improved yields.

### Embodiment 1

MOCVD Apparatus

The MOCVD apparatus according to this embodiment of the present invention is as shown in FIG. 1 and has flow channel 102 of 100 mm wide in the inner diameter and of a height of 10 mm. A plurality of protrusions were provided on the partition between source NH₃ gas line 106 and source MO gas line 107. The shape of protrusions 105 was hemispherical, the radius of the bottom surface thereof was 2 mm, and the height thereof was 2 mm. A plurality of protrusions 105 were provided 175 mm to 183 mm on the upstream side of the center of the substrate. Protrusions 105 were arranged periodically in such a pattern that the centers of three neighboring protrusions were 4 mm spaced from each other and make up the three apices of an equilateral triangle each side of which was 4 mm.

Epitaxial Growth of Nitride Semiconductor Layer

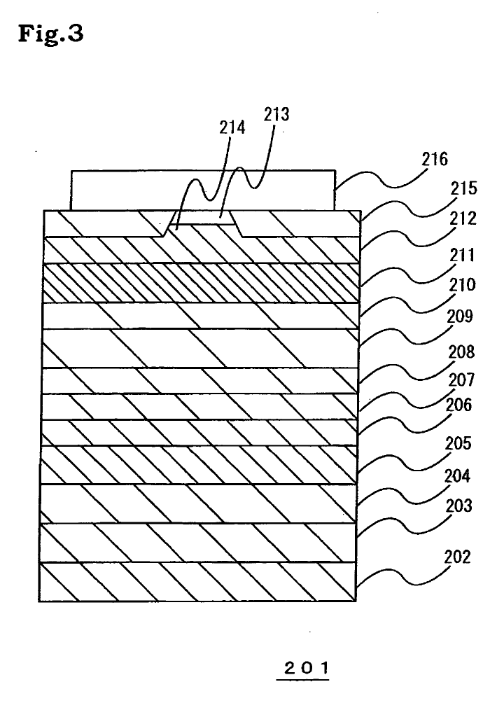

Next, a method for preparing a semiconductor laser device by forming nitride semiconductor layers over an n-type GaN substrate will be described. FIG. 3 is a schematic cross-section of a semiconductor laser device according to this embodiment of the present invention.

On n-type GaN substrate 203, n-type GaN layer 204 of a substrate temperature of 1100° C. and a thickness of lilm was formed by using the MOCVD apparatus shown in FIG. 1. The source gases used were NH₃ gas as a group V source gas and TMGa (trimethylgallium) or TEGa (triethylgallium) as a group III source gas. As a dopant material, silane (SiH₄) was added.

Next, on n-type GaN layer 204, three n-type cladding layers 205, 206, and 207 were grown. The substrate temperature was 1050° C., and TMAI (trimethylaluminum) or TEAI (triethylaluminum) was used as a group III source gas. The three n-type cladding layers include: as first layer 205, an n-type Al_{0.05}Ga_{0.95}N cladding layer of 2.3 μmthick; as second layer 206, an n-type Al_{0.08}Ga_{0.92}N cladding layer of 0.2 μmthick; and as third layer 207, an n-type Al_{0.5}Ga_{0.95}N cladding layer of 0.1 μmthick. As an n-type impurity, Si was added at 5×10¹⁷/cm³ to 1×10¹⁹/cm³.

Next, n-type GaN light guide layer 208 of 0.1 μm was grown (Si impurity concentration: 1×10¹⁶/cm³ to 1×10¹⁸/cm³).

The substrate temperature was then decreased to 800° C., and a three-periodic active layer (209, multi-quantum well structure) including a In_{0.1}Ga_{0.9}N well layer of 4 nm thick and a In_{0.01}Ga_{0.99}N barrier layer of 8 nm thick was grown. These layers were grown in the following order: barrier layer/well layer/barrier layer/well layer/barrier layer/well layer/barrier layer. When a barrier layer is grown on a well layer, or vice versa, a growth interruption is preferably provided for from 1 second to 180 seconds in that the flatness of each layer improves and the full width at half maximum of light reduces. In this case, SiH₄ was not optionally added in the barrier layer or in the barrier layer and well layer.

When As is added in active layer 209, the material used is AsH₃ (arsine) or TBAs (tertiary butyl arsine). When adding P in active layer 209, the material used is PH₃ (phosphine) or TBP (tertiary butyl phosphine). When Sb is added in active layer 209, the material used is TMSb (trimethylantimony) or TESb (triethylantimony). When forming active layer 209, the N material other than NH₃ may be N₂H₄ (hydrazine), C₂N₂H₈ (dimethylhydrazine), or organic substances containing N.

Next, the substrate temperature was increased to 1000° C. again, and p-type Al_{0.2}Ga_{0.8}N carrier block layer 210 of 20 nm thick, p-type GaN light guide layer 211 of 0.02 μm thick, p-type Al_{0.05}Ga_{0.95}N cladding layer 212 of 0.5 μm thick, and p-type GaN contact layer 213 of 0.1 μm thick were sequentially grown. As a p-type impurity, EtCP₂Mg (bis-ethyl cyclopentadienylmagnesium) was used, and Mg was added at 1×18¹⁸/cm³ to 2×10²⁰/cm³. The p-type impurity concentration ratio of p-type GaN contact layer 213 preferably increases in the direction of p-electrode 216. This reduces contact resistance resulting from formation of p-electrode 216. To remove the residual hydrogen in the p-type layers which prevents activation of Mg, which is a p-type impurity, a small amount of oxygen may be mixed during growth of the p-type layers.

After p-type GaN contact layer 213 was thus grown, the atomosphere of the reactor of the MOCVD apparatus underwent complete substitution with a nitrogen carrier gas and NH₃, and the temperature of the reactor was decreased at the rate of 60° C./minute. When the substrate temperature became 800° C., the supply of NH₃ was discontinued. This substrate temperature was maintained for 5 minutes, and then decreased to room temperature. The substrate temperature maintained is not limited to 800° C., but may be from 650° C. to 900° C. Standby time is preferably from 3 minutes to 10 minutes. The rate at which the substrate temperature is decreased is preferably 30° C./minute.

The grown films thus prepared were estimated by Raman measurement. Results show that the grown films already showed p-type characteristics without p-type annealing after removing the wafer out of the MOCVD apparatus. That is, Mg was confirmed to have been activated. It was also found that contact resistance resulting from p-type electrode formation was reduced. Further, a combination of the grown films and conventional p-type annealing further improved Mg activation.

While active layer 209 of the present invention starts by a barrier layer and ends with a barrier layer, an active layer which starts by a well layer and ends with a well layer gives similar preferable results. The number of the well layers is not limited to three. When the total number of the well layers was ten or less, the threshold current density was small and continuous oscillation was feasible at room temperature. Two or six well layers were especially preferable, where the threshold current density was small. The active layer may further contain Al.

While in this embodiment Si was not added as an impurity in the well layers and barrier layers, which constituted active layer 209, an impurity may be added therein. Addition of impurities such as Si enhanced light emission intensity. Examples of impurities that may be added include Si, O, C, Ge, Zn, and Mg. These impurities may be used alone or in combination of two or more thereof. A preferable total amount of the added impurities was approximately 1×17¹⁷/cm³ to 8×10¹⁸/cm³. Impurities were preferably added either in both of the well layer and barrier layer or in one of the layers.

P-type carrier block layer 210 may not necessarily have the composition Al_{0.2}Ga_{0.8}N. For example, a AlGaN layer with In added therein is preferable in that the layer requires a lower growth temperature to become positive, thus alleviating the damage to the active layer at the time of crystal growth. Further, while carrier block layer 210 was not an essential layer, provision thereof made the threshold current density smaller. This is because carrier block layer 210 has the function of confining carriers in the active layer. When the composition ratio of Al of carrier block layer 210 is increased, carrier confinement improves. When the composition ratio of Al is reduced while maintaining carrier confinement, carrier movement in the carrier block layer increases and electrical resistance reduces.

In this embodiment, a Al_{0.05}Ga_{0.95}N crystal and a Al_{0.08}Ga_{0.92}N crystal were used respectively for the n-type cladding layer and the p-type cladding layer. AlGaN crystals with an Al crystal composition of other than 0.05 and 0.08 may be used. When the Al composition ratio is increased, the energy gap difference and the refractive index difference between the cladding layer and active layer increase, and carriers and light are confined in the active layer effectively. This reduces the threshold current density laser oscillation. When the Al composition ratio is reduced while maintaining carrier and light confinement, carrier movement in the cladding layer increases and the operation voltage of the element reduces.

By employing a three-layer structure for the n-type AlGaN cladding layers, the vertical/lateral mode was rendered unimodal and light confinement efficiency was increased, thus improving the optical characteristics of the laser and reducing the laser threshold current density. The n-type AlGaN cladding layers are not limited to a three-layer structure; a single-layer structure and a multi-layer structure other than three provided similar preferable effects.

While in this embodiment the tertiary mixed crystal AlGaN was used for the cladding layer, the quaternary mixed crystal AlInGaN, AlGaNP, AlGaNAs, or the like may be used.

To reduce electrical resistance, p-type cladding layer 212 may have a superlattice structure composed of a p-type AlGaN layer and a p-type GaN layer, a superlattice structure composed of a p-type AlGaN layer and a p-type AlGaN layer, or a superlattice structure composed of a p-type AlGaN layer and a p-type InGaN layer.

Element-Making Process

Next, the epi-wafer composed of the n-type GaN substrate having formed thereon the various nitride semiconductor layers was removed out of the MOCVD apparatus, and was processed into nitride semiconductor laser device chips by the following process steps.

First, a ridge stripe portion that corresponded to laser light guide region 214 was formed. Specifically, the surface of the epiwafer was etched down to the middle or bottom of the carrier block layer with a stripe portion left unetched. The stripe width is from 1 pm to 3 pm, preferably 1.3 pm to 2 pm. Then, insulation film 215 was formed in the portions other than the ridge stripe portion. As the material for insulation film 215, AlGaN was used. For the insulation film, an oxide or nitride of silicon, titanium, zirconia, tantalum, aluminum, or the like may be used.

P-electrode 216 was formed on the unetched and exposed part of p-type GaN contact layer 213 and on insulation film 215 by deposition in the order Pd/Mo/Au. The material for p-electrode 216, other than Pd/Mo/Au, may be Pd/Pt/Au or Ni/Au.

Next, the other surface (substrate side) of the epiwafer was polished to a thickness of 80 μm to 200 μm, for ease of subsequent wafer division. N-type electrode 202 was formed on the other surface of the substrate by deposition in the order Hf/Al. The material for n-type electrode 202, other than Hf/Al, may be Hf/Al/Mo/Au/, Hf/Al/Pt/Au/, Hf/Al/W/Au, Hf/Au, Hf/Mo/Au, or an electrode material in which the Hf of any of the foregoing is replaced with Ti or Zr.

Lastly, the epiwafer was cleaved in a vertical direction to the ridge stripe direction, thus preparing a Fabry-Perot resonator with a resonator length of 600 μm. The resonator length is preferably from 250 μm to 1000 μm.

By this process step, the wafer was rendered a bar form in which laser devices 201 are lined alongside each other. The resonator edge side of a nitride semiconductor laser device in which the stripe is formed along the <1-100> direction is the <1-100> edge side of the nitride semiconductor crystal. In place of carrying out feedback at the edge side, a DFB (distributed feedback), which carries out feedback using a built-in diffraction grating, or a DBR (distributed bragg reflector), which carries out feedback using an externally built diffraction grating, may be used.

After forming the resonator edge side of the Fabry-Perot resonator, dielectric films of SiO₂ and TiO₂ having a 80% reflectivity were deposited alternately on the edge side, forming a dielectric multi-layer reflective film. The dielectric multi-layer reflective film may be formed of other dielectric materials than the above materials.

After this process step, the bar was divided into laser devices to obtain semiconductor laser device 201 shown in FIG. 3. A laser light wave guide region was provided in the center of the laser chip, making the lateral width of the laser device 300 μm.

### COMPARATIVE EXAMPLE 1

A semiconductor laser device was prepared in a similar manner by using a MOCVD apparatus in which protrusions were not provided in the flow channel.

Characteristics of the Semiconductor Laser Devices

<Laser Emission Wavelength >

The semiconductor laser device according to the present invention accomplished a laser emission wavelength of 405±1 nm, a laser output of 60 mW, and a laser oscillation life of 5000 hours or more at an atmosphere temperature of 70° C.

On the other hand, the semiconductor laser device of the comparative example had a laser emission wavelength of 405±3 nm.

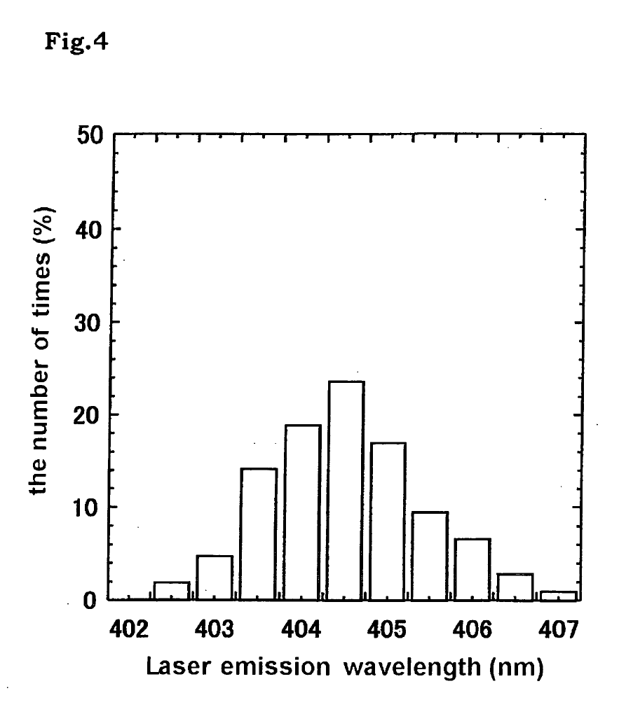

FIG. 4 shows a graph showing the number of times (%) of laser emission wavelength in the semiconductor laser device according to comparative example 1. The range of laser emission wavelength was 404.5±3 nm.

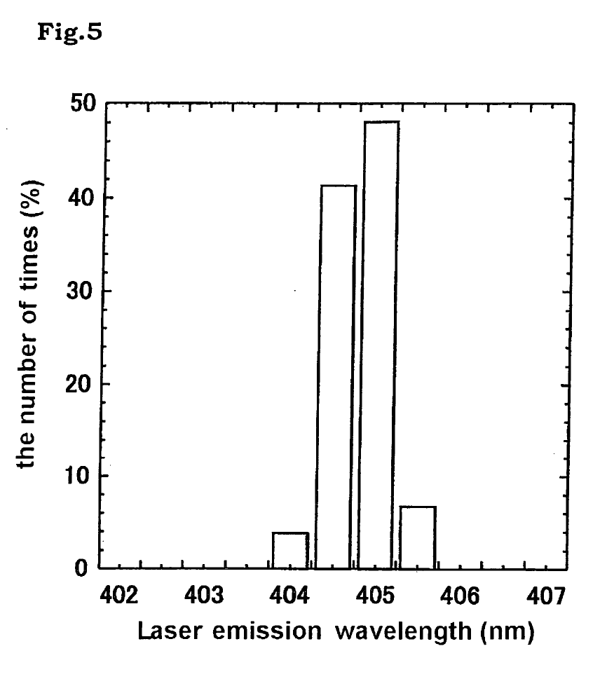

FIG. 5 shows a graph showing the number of times (%) of laser emission wavelength in the semiconductor laser device according to an embodiment of the present invention. The range of laser emission wavelength was 405±1 nm.

Thus, it has been found that the nitride semiconductor laser produced by the apparatus for producing a nitride semiconductor of the present invention improves laser emission wavelength uniformity throughout the substrate plane.

<Thickness Distribution of the Semiconductor Layers>

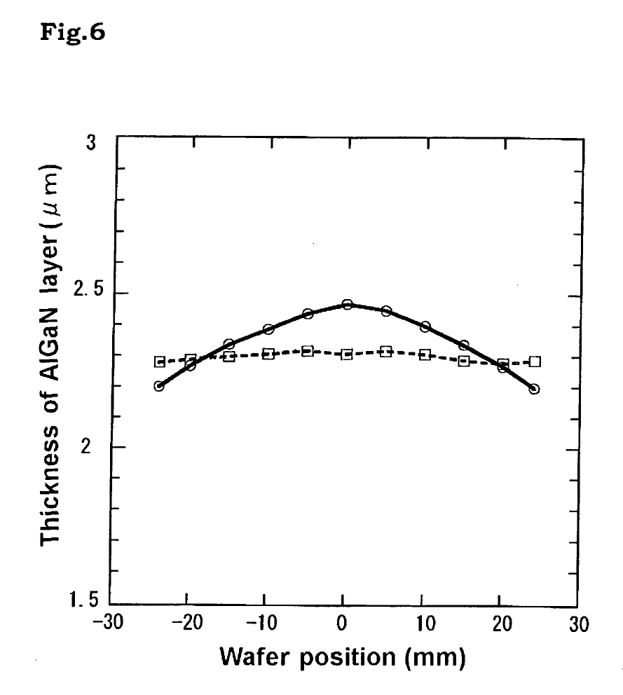

FIG. 6 is a graph showing the in-plane distribution (%) of thickness of the first n-type AlGaN cladding layer of the nitride semiconductor laser according to this embodiment and the in-plane distribution (%) of thickness of the first n-type AlGaN cladding layer of the nitride semiconductor laser according to comparative example 1. In FIG. 6, the dotted line indicates the in-plane distribution (%) of thickness of the first n-type AlGaN cladding layer of the nitride semiconductor laser according to this embodiment, and the solid line indicates the in-plane distribution (%) of thickness of the first n-type AlGaN cladding layer of the nitride semiconductor laser according to comparative example 1. Also in the figure, the wafer position on the lateral axis has the starting point 0 corresponding to the center of the substrate. The design thickness of the first n-type AlGaN cladding layers was 2.3 μm.

It can be seen from FIG. 6 that the thickness range of the nitride semiconductor laser according to this embodiment is from 2.28 μm to 2.32 μm, a 1% or less thickness variation. On the other hand, the thickness range of the nitride semiconductor laser according to the comparative example is from 2.20 μpm to 2.47 μm, a 8% or less thickness variation. Thus, it has been found that in the nitride semiconductor laser according to the present invention, the thickness of the first n-type AlGaN layer is uniform throughout the substrate plane.

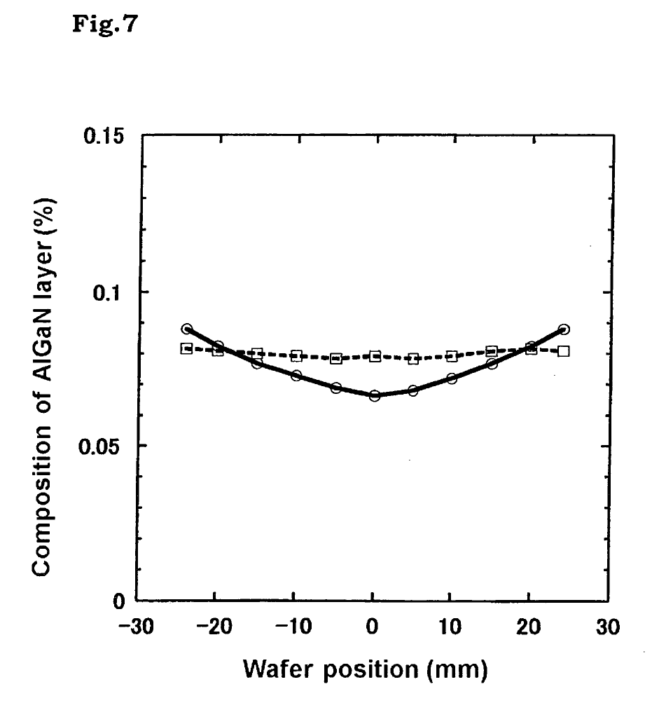

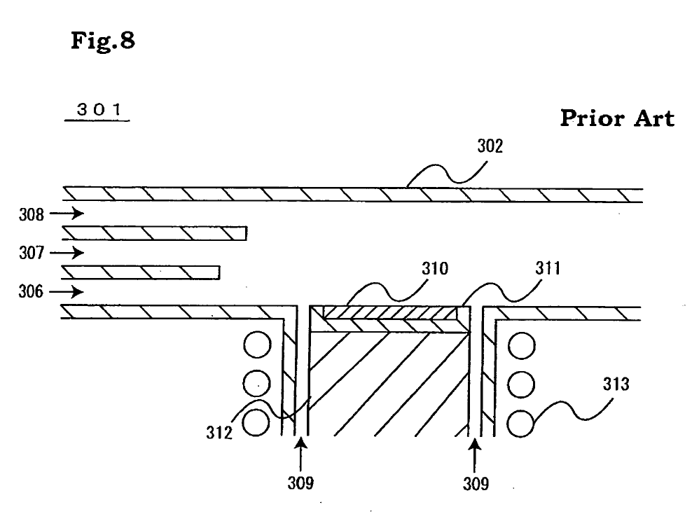

FIG. 7 is a graph showing the in-plane distribution (%) of Al composition of the first n-type AlGaN cladding layer of the nitride semiconductor laser according to this embodiment and the in-plane distribution (%) of Al composition of the first n-type AlGaN cladding layer of the nitride semiconductor laser according to comparative example 1. In FIG. 7, the dotted line indicates the in-plane distribution (%) of Al composition of the first n-type AlGaN cladding layer of the nitride semiconductor laser according to this embodiment, and the solid line indicates the in-plane distribution (%) of Al composition of the first n-type AlGaN cladding layer of the nitride semiconductor laser according to comparative example 1. Also in the figure, the wafer position on the lateral axis has the starting point 0 corresponding to the center of the substrate. The design Al composition of the first n-type AlGaN cladding layers was 0.08.

It can be seen from FIG. 7 that the Al composition of the first n-type AlGaN cladding layer according to this embodiment is from 0.078 to 0.082, a 3% or less Al composition variation. On the other hand, the Al composition of the first n-type AlGaN cladding layer according to comparative example 1 is from 0.066 to 0.088, a 18% or less Al composition variation. Thus, it has been found that in the nitride semiconductor laser according to the present invention, the Al composition of the first n-type AlGaN cladding layer is uniform throughout the substrate plane.

### Embodiment 2

A nitride semiconductor laser was prepared in a similar manner to Embodiment 1 by using a MOCVD apparatus with protrusions provided on the inner wall of the upper surface of the flow channel, the inner wall of the lower surface of the flow channel, and the upper and lower surfaces of the partition between the protection gas line and III gas line. This nitride semiconductor laser also showed improvement in the in-plane uniformity of the laser emission wavelength and in the uniformity of Al composition of the first n-type AlGaN cladding layer throughout the substrate plane.

A nitride semiconductor laser was prepared in a similar manner to Embodiment 1 by using a MOCVD apparatus with the protrusions campanulate-shaped (trigonal pyramid-, quadrangular pyramid-, and cone-shaped) and column-shaped (triangular prism-, quadratic prism-, and cylinder-shaped) rather than hemisphere-shaped This nitride semiconductor laser also showed improvement in the in-plane uniformity of the laser emission wavelength and in the uniformity of Al composition of the first n-type AlGaN cladding layer throughout the substrate plane.

A nitride semiconductor laser was prepared in a similar manner to Embodiment 1 by using a MOCVD apparatus in which the sizes of the protrusions were changed to a height of 1 mm to 10 mm and a width of 1 mm to 10 mm. This nitride semiconductor laser also showed improvement in the in-plane uniformity of the laser emission wavelength and in the uniformity of Al composition of the first n-type AlGaN cladding layer throughout the substrate plane. Especially excellent were protrusions of 2 mm to 8 mm high and 2 mm to 8 mm wide.

### COMPARATIVE EXAMPLE 2

Ntride semiconductor lasers were prepared in a similar manner to Embodiment 1 by using a MOCVD apparatus with protrusions provided on over-the-substrate flow channel 115, and using a MOCVD apparatus with protrusions provided on downstream flow channel 116. This nitride semiconductor laser did not show improvement in the in-plane uniformity of the laser emission wavelength and in the uniformity of Al composition of the first n-type AlGaN cladding layer throughout the substrate plane, as compared with conventional examples.

### Embodiment 3

Even when the size of the substrate was increased from 2 inches to 3 inches, the variation of laser emission wavelength of the nitride semiconductor laser produced by the apparatus for producing a nitride semiconductor according to the present invention was restricted to Inm or less throughout the substrate. Further, the variation of mixed crystal ratio of the AlGaN layer and the variation of thickness of the AlGaN layer throughout the substrate were restricted to several %. The MOCVD used here had a flow channel of 150 mm wide in the inner width and of a height of 12 mm. The shape of the protrusions was hemispherical, and the radius of the bottom surface was 2 mm and the height was 2 mm. Two or more protrusions were provided on the flow channel 220 mm to 236 mm on the upstream side of the center of the substrate. Also, two or more protrusions were arranged periodically in such a pattern that the centers of three neighboring protrusions were 4 mm spaced from each other and made up the three apices of an equilateral triangle each side of which is 4 mm.

As has been described hereinbefore, according to the present invention, a plurality of protrusions are provided on an inner wall of the flow channel in the apparatus for producing a nitride semiconductor. By this structure the concentration ratio distribution of the source gases becomes uniform throughout the substrate plane. This results in each of the nitride semiconductor layers uniformly formed over the plane.

The laser emission wavelength of the nitride semiconductor laser produced by using the apparatus for producing a nitride semiconductor according to the present invention has its variation restricted to 1 nm or less throughout the substrate plane. Further, the variation of mixed crystal ratio of the AlGaN layer and the variation of thickness of the AlGaN layer plane are restricted to several % throughout the substrate. This results in nitride semiconductor laser devices with less varied optical characteristics and improved yields.

Even with a large-sized substrate, provision of protrusions according to the present invention makes it easy to make the concentration ratio distribution of the source gases uniform.

Even when the size of the substrate is increased from 2 inches to 3 inches, the variation of laser emission wavelength of the nitride semiconductor laser produced by the apparatus for producing a nitride semiconductor according to the present invention is restricted to 1 nm or less throughout the substrate. Further, the variation of mixed crystal ratio of the AlGaN layer and the variation of thickness of the AlGaN layer are restricted to several % throughout the substrate.

As a result, even when the size of the substrate over which nitride semiconductor layers are to be laminated is increased, the characteristics of the nitride semiconductor laser are kept uniform.

What is claimed is:

1. An apparatus for producing a nitride semiconductor by crystal-growing the nitride semiconductor on a substrate by diffusing a gas containing a source gas of group III element and a source gas of group V element, the diffusing of the gas being in parallel with the substrate and from upstream to downstream, the apparatus comprising:
a flow channel housing the substrate and-for allowing the gas to flow in the flow channel; and
a plurality of protrusions formed on an inner wall of the flow channel.

2. The apparatus for producing a nitride semiconductor according to claim 1, wherein the protrusions are formed on the upstream side of the substrate in the flow channel.

3. The apparatus for producing a nitride semiconductor according to claim 1, further comprising a partition for causing the source gas of group III element and the source gas of group V element to be introduced separately into the flow channel, the partition being formed on an upstream portion of the flow channel and extending in a horizontal direction, the apparatus wherein
the protrusions are formed on at least one of the upper and lower surfaces of the partition.

4. The apparatus for producing a nitride semiconductor according to claim 3, wherein the protrusions are formed on both of the upper and lower surfaces of the partition.

5. The apparatus for producing a nitride semiconductor according to claim 1, wherein the protrusions are hemisphere-shaped, campanulate-shaped, or column-shaped.

6. The apparatus for producing a nitride semiconductor according to claim 5, wherein the protrusions are hemisphere-shaped.

7. The apparatus for producing a nitride semiconductor according to claim 5, wherein the protrusions are campanulate-shaped or column-shaped, a bottom surface of each of the protrusions thus shaped being equilateral-polygon-shaped or circle-shaped.

8. The apparatus for producing a nitride semiconductor according to claim 3, wherein centers of bottom surfaces of the protrusions are equally spaced from each other.

9. The apparatus for producing a nitride semiconductor according to claim 8, wherein the plurality of protrusions are arranged to become an equilateral triangle if the center of each bottom in three adjoined protrusions is connected.

10. The apparatus for producing a nitride semiconductor according to claim 8, wherein the plurality of protrusions may be arranged to become an equilateral quadrangle if the center of each bottom in four adjoined protrusions is connected.

11. The apparatus for producing a nitride semiconductor according to claim 1, wherein the size of the substrate is from 2 to 3 inches.

12. A method for producing a nitride semiconductor by crystal-growing the nitride semiconductor on a substrate by supplying thereonto a mixture gas containing a source gas of group III element and a source gas of group V element, the method comprising the steps of:
stirring the source gas of group III element and the source gas of group V element; and
supplying the stirred source gases onto the substrate.

13. The method for producing a nitride semiconductor according to claim 12, wherein:
the stirring is separate for each of the source gas of group III element and the source gas of group V element; and
the separately stirred source gases are supplied onto the substrate.

14. The method for producing a nitride semiconductor according to claim 12, wherein the supplying of the source gas of group III element and the source gas of group V element comprises diffusing the source gases in parallel with the substrate and from upstream to downstream.

15. The method for producing a nitride semiconductor according to claim 12, wherein the crystal-growing of the nitride semiconductor is carried out by the metal organic chemical vapor deposition method.

16. The method for producing a nitride semiconductor according to claim 12, wherein the size of the substrate is from 2 to 3 inches.

17. A nitride semiconductor laser device produced by a method according to claim 12.
